(19) United States
(12) Patent Application Publication
(10) Pub. No.: US 2004/0191933 A1
(43) Pub. Date: Sep. 30, 2004

(54) Silicon-on-insulator devices and methods for fabricating the same

(76) Inventor: Kramadhati V. Ravi, Atherton, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/824,458

(22) Filed: Apr. 13, 2004

Related U.S. Application Data
(62) Division of application No. 10/314,015, filed on Dec. 5, 2002.

(51) Int. Cl. G01R 31/26

(52) U.S. Cl. 438/14

(57) ABSTRACT

Techniques for local and selective thinning of silicon using a combination of real time metrology for film thickness measurement accompanied by local etching of the silicon to thin the silicon to the desired value. Etching is accomplished using a miniature plasma etcher with activated etch gases. The etch tool and the metrology tool are stepped across the wafer surface to achieve wafer level thinning of the top silicon.

### RELATED APPLICATIONS

This application is a divisional of U.S. patent application Ser. No. 10/314,015, filed on Dec. 5, 2002.

### FIELD

The subject matter disclosed herein generally relates to techniques to manufacture semiconductor devices.

### DESCRIPTION OF RELATED ART

Silicon-on-insulator (“SOI”) technology is an emerging technique for fabricating high-speed Metal-Oxide-Semiconductor (MOS) and Complementary Metal Oxide Semiconductor (CMOS) circuits in very large scale integrated (VLSI) circuits. An SOI wafer may have a thin single crystal layer of semiconductor material (e.g., silicon) formed on an insulator (e.g., a buried oxide film) that reduces capacitive coupling between the layer of semiconductor material and an underlying substrate material.

One process to manufacture an SOI wafer is the Separation by Implantation of Oxygen (SIMOX) process. FIG. 1 depicts an example SIMOX fabrication process. The SIMOX process utilizes oxygen (O) ion implantation and annealing to form a buried oxide layer 104. The thickness of the silicon layer 102 may be controlled by controlling the depth that oxygen ions are implanted and hence the depth that the buried oxide 104 is formed. The buried oxide 104 may be formed over a substrate 106. This process has not been demonstrated for very thin films of silicon. Lack of uniformity of silicon layer thickness, silicon layer defects, and process control may limit the thicknesses of silicon layer 102 that can be achieved.

Another approach to manufacture an SOI wafer may use a layer transfer process. For example, FIG. 2 depicts an example layer transfer process. A layer transfer process may involve implanting hydrogen (H) ions into a silicon wafer 202 to form hydrogen implant layer 205; bonding surface 203 of the silicon wafer 202 to an oxidized surface of a silicon wafer 204; and separating a portion of the top silicon layer at the hydrogen implant layer 205 to leave behind a thin layer of silicon (such thin layer of silicon is shown as silicon layer 210). The process forms an SOI wafer having a thin silicon layer 210 separated from substrate 214 by oxide 212. Reducing a thickness of silicon layer 210 involves a high degree of control over the hydrogen implantation process. Further, hydrogen implantation creates micro voids within silicon. The micro voids may protrude from silicon layer 210 in an undesired manner.

Another approach to manufacture SOI wafers may involve oxidizing the top layer of silicon film (for example layer 102 of the structure 100 of FIG. 1 may correspond to a top layer of silicon film) and removing the oxidized layer so that a desired thickness of silicon film remains. This process however may also have limitations on silicon film layer thickness as the film thickness approaches the 5 to 10 nm range because of the difficulty of process control and maintaining uniformity of silicon film layer thickness across the wafer surface. Oxidation may also create defects within the silicon film layer.

### DESCRIPTION OF THE DRAWINGS

FIG. 1 depicts an example SIMOX fabrication process.

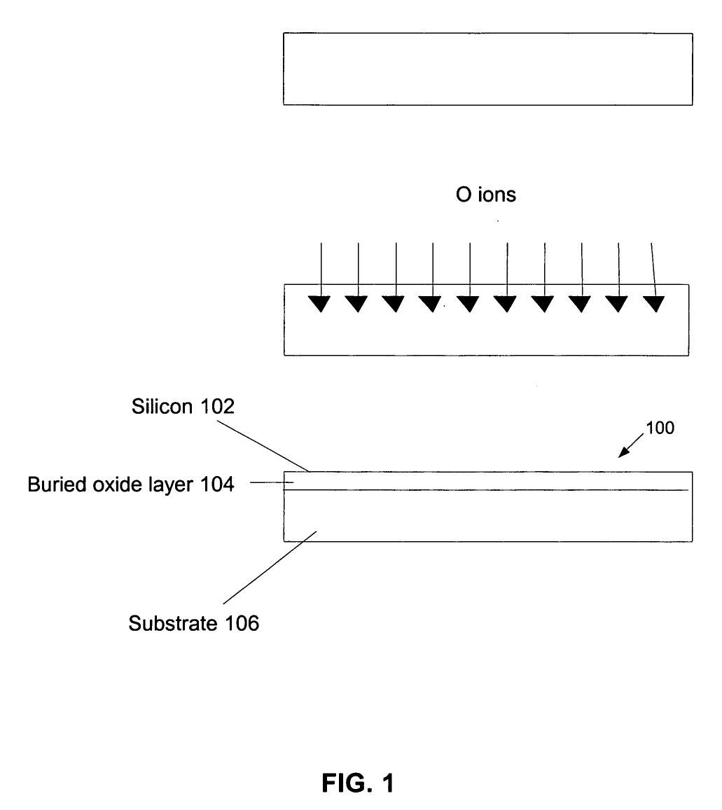

FIG. 2 depicts an example layer transfer process.

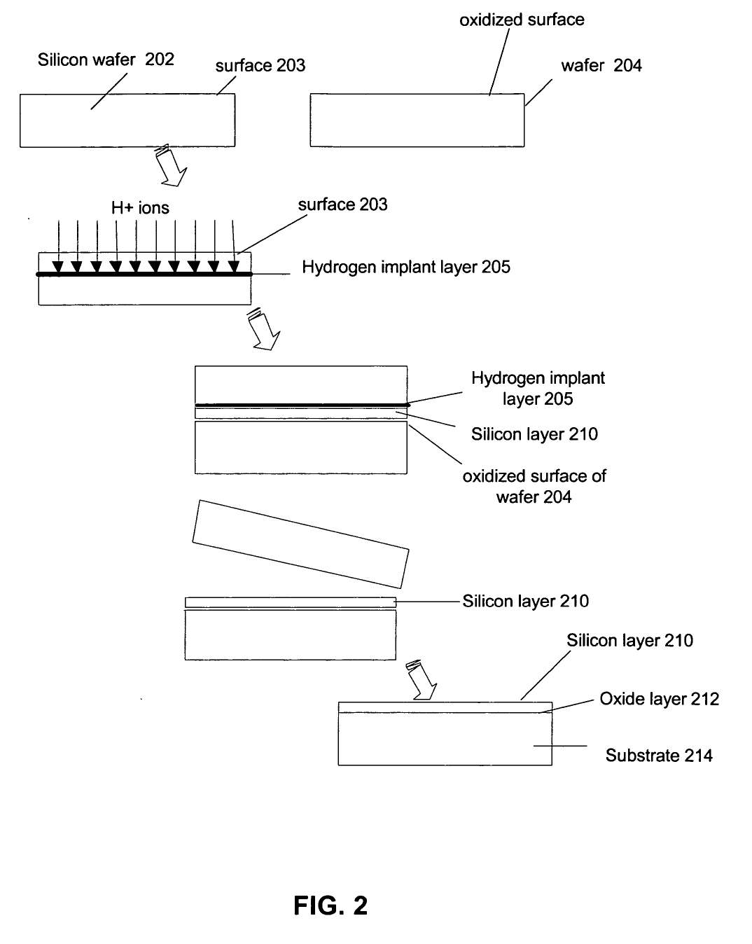

FIG. 3 depicts a suitable fabrication system that can be used to construct SOI in accordance with an embodiment of the present invention.

FIG. 4 depicts an example SOI wafer.

FIG. 5 depicts one possible process that may be used to construct an SOI n accordance with an embodiment of the present invention.

FIG. 6 depicts an example execution of a process of FIG. 5, in accordance embodiment of the present invention.

Note that use of the same reference numbers in different figures indicates the like elements.

### DETAILED DESCRIPTION

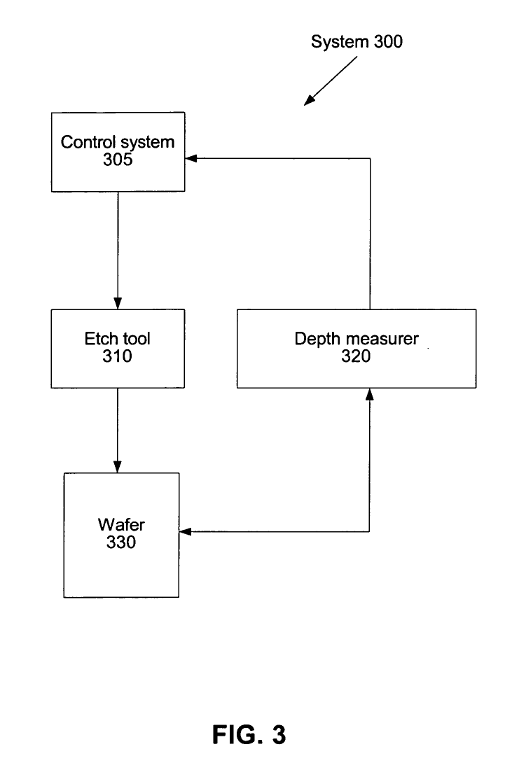

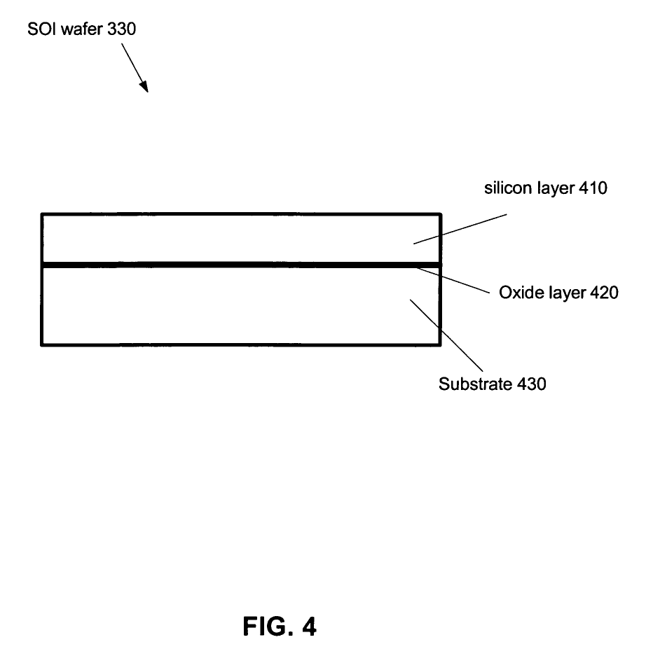

In accordance with an embodiment of the present invention, FIG. 3 depicts one possible implementation of a fabrication system 300 that can be used to construct SOI wafers such as an SOI wafer 330 of FIG. 4. As depicted in FIG. 4, SOI wafer 330 may include a silicon layer 410 formed over an oxide layer 420. Oxide layer 420 may be formed over substrate 430. Fabrication system 300 may utilize etch tool 310 and depth measurer 320 to adjust a thickness of the silicon layer 410 of SOI wafer 330. A control system 305 may be used to coordinate the actions of etch tool 310 and depth measurer 320. For example, control system 305 may control the amount the etch tool 310 and depth measurer 320 move across the surface of silicon layer 410 as well as the amount of silicon that etch tool 310 removes from silicon layer 410. For example, control system 305 may be implemented as any of or a combination of: hardwired logic, software stored by a memory device and executed by a microprocessor, firmware, an application specific integrated circuit (ASIC), and/or a field programmable gate array (FPGA).

Depth measurer 320 may measure a thickness of a silicon layer 410 of SOI wafer 330. One implementation of depth measurer 320 may use light to measure the thickness of silicon layer 410 of SOI wafer 330. For example, one implementation of depth measurer 320 may be a spectroscopic elipsometry device or other metrology device.

One implementation of etch tool 310 may include a plasma generator that uses silicon etching and carrier gases to remove silicon from silicon layer 410 of SOI wafer 330. Suitable silicon etching gases include HF₆, C₂F₂, or CF₄. A suitable carrier gas includes argon.

In one implementation, the etch tool 310 and the depth measurer 320 may be stepped across the SOI wafer 330 to respectively locally measure the thickness of silicon layer 410 and selectively etch portions of silicon layer 410. In one implementation, based on the silicon layer 410 thickness information from the depth measurer 320, etch tool 310 may be activated to remove a programmed thickness of silicon layer 410.

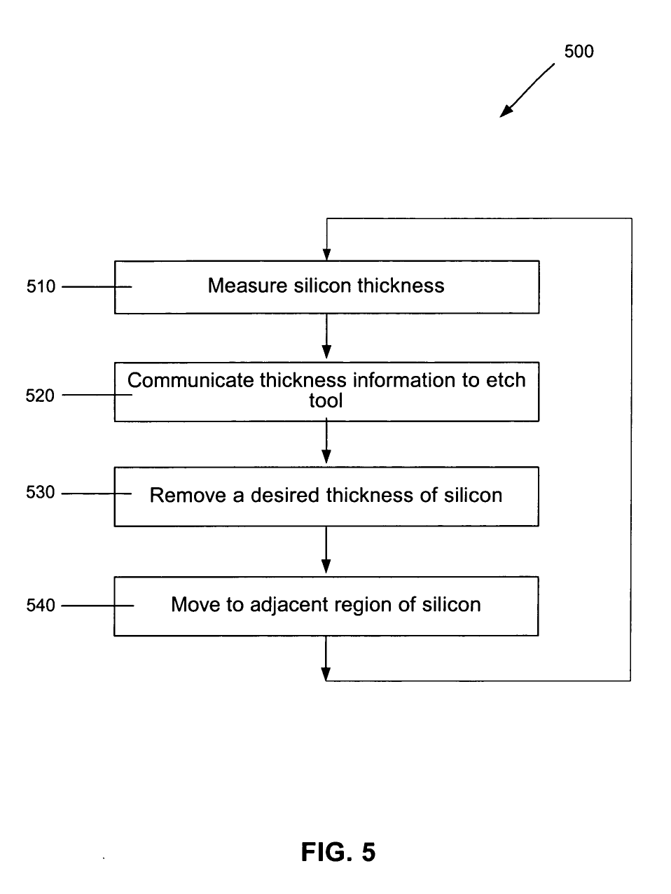

In accordance with an embodiment of the present invention, FIG. 5 depicts one possible process that may be used to adjust a thickness of a portion of silicon layer of an SOI wafer. Action 510 includes measuring a local thickness of silicon layer 410. For example, depth measurer 320 may measure a thickness of silicon layer 410 in a region where etch tool 310 may remove silicon from the surface of silicon layer 410.

Action 520 includes communicating the thickness of the selected region of silicon layer 410 to control system 305. For example, depth measurer 320 may communicate the thickness of silicon layer 410 determined in action 510 to control system 305.

Action 530 includes removing a portion of the surface of silicon layer 410 to a specified depth for the selected region identified in action 510. For example, based upon the thickness of the selected region of silicon layer 410 communicated in action 520 and a programmed intended total thickness of the selected region of silicon layer 410, the control system 305 may determine what thickness of silicon layer 410 that etch tool 310 should remove. In some implementations, a user can provide a topographical map to control system 305 having data of desired thicknesses for different regions of silicon layer 410. For example, the topographical map can divide the surface of silicon layer 410 into multiple regions, where each region is the maximum area from which the etch tool 310 can remove silicon. Based upon the thickness data and specific region, the control system 305 may program the etch tool 310 to remove a certain thickness from silicon layer 410.

Action 540 includes moving depth measurer 320 to an adjacent region of the surface of silicon layer 410. Action 510 follows action 540.

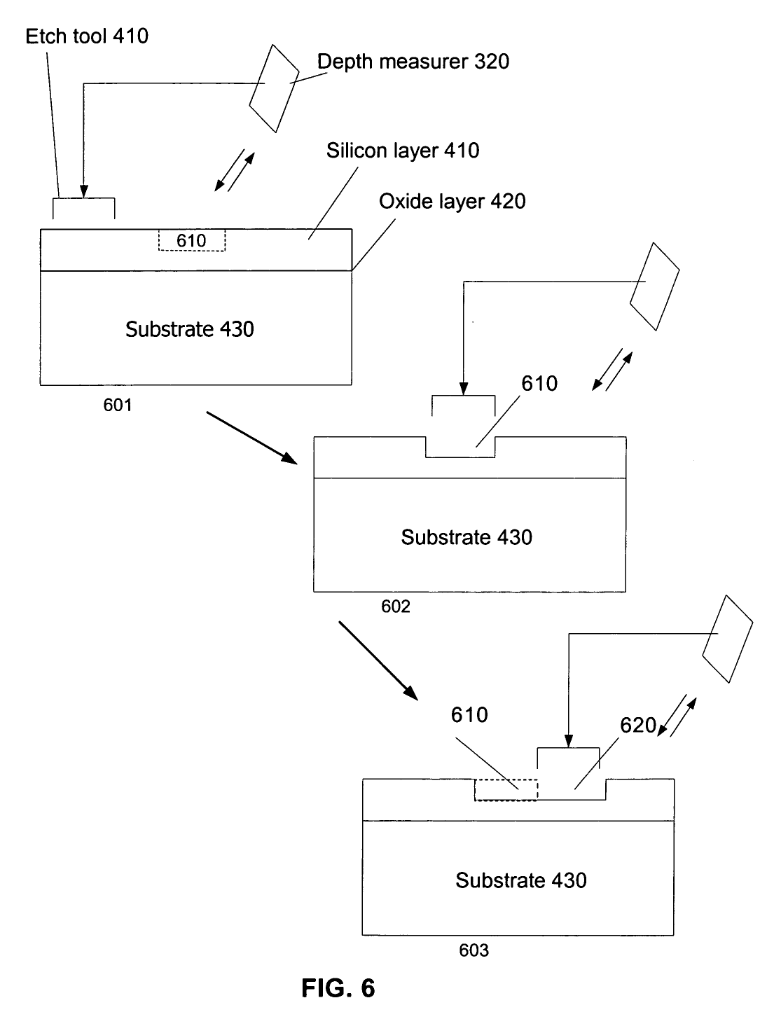

FIG. 6 depicts an example execution of the process 500. This example includes scenarios 601 to 603. In scenario 601, the depth measurer 320 may examine a thickness of a region 610 of silicon layer 410 and communicate the thickness of region 610 to control system 305. Scenario 601 may result from actions 510 and 520. In scenario 602, control system 305 programs etch tool 310 to remove a programmed thickness of silicon layer 410 from the selected region 610. Scenario 602 may result from action 530. Scenario 603 may depict an execution of actions 510 to 540 for a next adjacent region 620 of silicon layer 410.

The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. (Deleted)

2. (Deleted)

3. (Deleted)

4. (Deleted)

5. (Deleted)

6. (Deleted)

7. A system comprising:
a wafer comprising at least one layer;
a depth measurer to measure a thickness of a selected region of an exposed layer of the wafer; and
an etch tool to selectively remove a thickness of the exposed layer in response to the measured thickness being greater than a specified thickness of the exposed layer of the selected region.

8. The system of claim 7, further comprising a control system to store a map associating thicknesses of the exposed layer for at least two regions of the exposed layer.

9. The system of claim 7, wherein the exposed layer comprises a silicon layer.

10. The system of claim 7, wherein the depth measurer comprises a spectroscopic elipsometry device.

11. The system of claim 7, wherein the etch tool comprises a plasma generator.

12. The system of claim 7, wherein the wafer comprises a silicon-on-insulator device further comprising a silicon layer separated from a substrate by an oxide layer.

13. An apparatus comprising:
a substrate;
a silicon layer; and
an oxide layer electrically insulating the silicon layer from the substrate, wherein a thickness of the silicon layer is formed by removing at least a portion of the silicon layer using a plasma generator.

14. The apparatus of claim 13, wherein an amount to remove from a surface of the silicon layer is determined using a spectroscopic elipsometry device.

15. The apparatus of claim 14, wherein the plasma generator removes at least a portion of the silicon layer based upon a map specifying thicknesses of at least two regions of the silicon layer.
